(19) United States
(12) Patent Application Publication
(10) Pub. No.: US 2023/0340663 A1
(43) Pub. Date: Oct. 26, 2023

(54) PLASMA-ENHANCED METHOD AND SYSTEM FOR FORMING A SILICON OXYCARBIDE LAYER AND STRUCTURE FORMED USING SAMEPLASMA-ENHANCED METHOD AND SYSTEM FOR FORMING A SILICON OXYCARBIDE LAYER AND STRUCTURE FORMED USING SAME

(71) Applicant: ASM IP Holding B.V., Almere (NL)

(72) Inventors: Fanyong Ran, Tokyo (JP); Zecheng Liu, Tokyo (JP); Tomohiro Kubota, Tokyo (JP); Takashi Yoshida, Tokyo (JP); Kai Okabe, Kawasaki-shi (JP)

(21) Appl. No.: 18/137,930

(22) Filed: Apr. 21, 2023

Related U.S. Application Data
(60) Provisional application No. 63/334,872, filed on Apr. 26, 2022.

(51) Int. Cl. C23C 16/455; C23C 16/32; C23C 16/52

(52) U.S. Cl. CPC C23C 16/32; C23C 16/45531; C23C 16/4554; C23C 16/45553; C23C 16/52

(57) ABSTRACT

Methods of forming a silicon oxycarbide layer on a surface of a substrate are disclosed. Exemplary methods include providing an oxygen-free reactant to a reaction chamber and performing one or more deposition cycles, wherein each deposition cycle includes providing a silicon precursor to the reaction chamber for a silicon precursor pulse period and providing plasma power for a plasma power period to form the silicon oxycarbide layer. Exemplary silicon precursors comprise a molecule comprising silicon, oxygen, carbon, and optionally nitrogen. The silicon precursor can further include one or more of (i) one or two silicon-oxygen bonds, (ii) one or two silicon-carbon bonds, or (iii) one carbon-carbon double bond.

### CROSS-REFERENCE TO RELATED APPLICATIONS

This application claims priority to U.S. Provisional Pat. Application Serial No. 63/334,872 filed Apr. 26, 2022 titled PLASMA-ENHANCED METHOD AND SYSTEM FOR FORMING A SILICON OXYCARBIDE LAYER AND STRUCTURE FORMED USING SAME, the disclosure of which is hereby incorporated by reference in its entirety.

### FIELD OF THE INVENTION

The present disclosure generally relates to methods and systems for forming structures suitable for forming electronic devices. More particularly, examples of the disclosure relate to methods and systems for forming layers comprising silicon oxycarbide.

### BACKGROUND OF THE DISCLOSURE

During the manufacture of electronic devices, such as field effect transistors, spacers, and particularly, low dielectric constant or low-k spacers, can be used to, for example, suppress coupling between nearby device components that might otherwise occur. As a size of the transistors decreases, such coupling can become increasingly problematic.

Recently, use of silicon oxycarbide has gained interest for use as low-k spacer material in, for example, three-dimensional field effect transistors, such as FinFET and gas-all-around devices. However, formation of silicon oxycarbide spacer material with desired deposition rate, dielectric constant, wet etch ratio, and conformality has been challenging. Indeed, often times, attempts to improve one or more such properties results in a negative impact on one or more of the other properties.

Plasma-enhanced deposition processes have been employed to improve a deposition rate of silicon oxycarbide. While use of a plasma during deposition has increased the deposition rate and can allow for lower deposition temperatures, silicon oxycarbide with desired wet etch rates, dielectric constant, and conformality remains a challenge.

Accordingly, improved methods of forming silicon oxycarbide and of achieving desired spacer material properties are desired. Further, device structures, which include such patterned structures, are also desired. Systems for performing the method are also desired.

Any discussion of problems and solutions set forth in this section has been included in this disclosure solely for the purpose of providing a context for the present disclosure, and should not be taken as an admission that any or all of the discussion was known at the time the invention was made.

### SUMMARY OF THE DISCLOSURE

Various embodiments of the present disclosure relate to methods of forming a silicon oxycarbide layer. The silicon oxycarbide layer can be used in the formation of devices, such as semiconductor devices and other electronic devices. More particularly, as described in more detail below, the silicon oxycarbide layer may be well suited for use in the formation of (e.g., low-k) spacers during the formation of an electronic device.

While the ways in which various embodiments of the present disclosure address drawbacks of prior methods and systems are discussed in more detail below, in general, various embodiments of the disclosure provide improved methods of forming a silicon oxycarbide layer with desired properties, such as a relatively low etch rate, a relatively low dielectric constant, relatively good adhesion to adjacent layer(s), and relatively good or uniform within substrate (e.g., wafer) and substrate-to-substrate thickness and property (e.g., density or porosity) uniformity.

In accordance with examples of the disclosure, a method of forming a silicon oxycarbide layer on a surface of a substrate is disclosed. The method can be used for forming, for example, low-k spacers during the formation of electronic devices. An exemplary method includes providing a substrate within a reaction chamber of a reactor, providing an oxygen-free reactant to the reaction chamber, and performing one or more deposition cycles, wherein each deposition cycle includes providing a silicon precursor to the reaction chamber for a silicon precursor pulse period and providing plasma power to an electrode for a plasma power period to form a plasma within the reactor. In accordance with examples of the disclosure, the silicon precursor comprises a molecule comprising silicon, oxygen, carbon, and optionally nitrogen. The silicon precursor can further include one or more of (i) one or two silicon-oxygen bonds, (ii) one or two silicon-carbon bonds, or (iii) one carbon-carbon double bond. As set forth in more detail below, use of such precursors allows for formation of silicon oxycarbide layers with relatively high deposition rates and other desired properties, such as low etch rate (e.g., a wet etch rate in 0.5% dilute hydrofluoric acid of less than 1 nm/minute) and low dielectric constant (e.g., less than 4.5 or less than 4, or between about 3.5 and about 4.25). In accordance with further examples of the disclosure, the oxygen-free reactant comprises one or more of argon (Ar) and hydrogen (H₂). In accordance with further examples, a plasma power on-time duty cycle during the step of providing plasma power can be greater than 0 and less than 75% or between about 10 and about 50%.

In accordance with further embodiments of the disclosure, a structure is provided. The structure can include a layer formed according to a method as set forth herein. In accordance with examples of these embodiments, the structure can include a spacer formed using a method described herein.

In accordance with yet additional examples of the disclosure, a system configured to perform a method and/or form a device structure as described herein is provided.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with further examples of the disclosure.

FIGS. 2 and 3 illustrate a timing sequence in accordance with examples of the disclosure.

FIG. 4 illustrates a structure including a spacer formed in accordance with examples of the disclosure.

FIG. 5 illustrates a system in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of forming a silicon oxycarbide layer on a surface of a substrate, to structures including the oxycarbide layer formed using the methods, and to systems for performing the methods. As described in more detail below, exemplary methods can be used to form structures suitable for forming electronic devices. For example, exemplary methods can be used to form spacers suitable for use in formation of three-dimensional device structures used in the formation of, for example, FinFET and gate-all-around devices. As further set forth in more detail below, exemplary methods and systems can provide desirable silicon oxycarbide layer deposition rates, while maintaining desired properties (e.g., dielectric constant, etch rate, etch selectivity, and the like) of the deposited silicon oxycarbide.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor. In some cases, a reactant can include an otherwise inert gas that has been activated using an excitation source, such as a plasma.

The term “carrier gas” as used herein may refer to a gas that is provided to a reaction chamber together with one or more precursors. Exemplary carrier gases include N₂, H₂, and noble gases, such as He, Ne, Kr, Ar and Xe. By way of particular examples, the carrier gas can include one or more of hydrogen (H₂), nitrogen (N₂), argon (Ar), or helium (He), in any combination. In some cases, a dilution gas can be or include a carrier gas.

As opposed to a carrier gas, a purge gas may be provided to a reaction chamber separately, i.e., not together with one or more precursors. This notwithstanding, gases which are commonly used as a carrier gas may also be used as a purge gas, even within the same process. For example, in a cyclic deposition-etch process, argon used as a carrier gas may be provided together with one or more precursors during deposition pulses, and argon used as a purge gas may be used to separate deposition and etch pulses. Of course, argon may be replaced by another suitable inert gas, such as H₂, or a noble gas, such as He, Ne, Kr, Ar, and Xe, or any combination thereof. Hence, it is the manner of how a gas is provided to the reaction chamber that determines whether a gas serves as a purge gas or a carrier gas in a specific context. Thus, as used herein, the term “purge” may refer to a procedure in which an inert or substantially inert gas is provided to a reaction chamber in between two pulses of gases that may react with each other. For example, a purge gas may be provided between precursor pulses. It shall be understood that a purge can be affected either in time or in space, or both. For example, in the case of temporal purges, a purge step can be used, e.g., in the temporal sequence of providing a precursor to a reaction chamber and then providing a purge gas to the reaction chamber, wherein the substrate on which a layer is deposited does not move.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various features, such as recesses, lines, and the like formed within or on at least a portion of a layer of the substrate. By way of particular examples, a substrate can include a protrusion or a recess on which a spacer is formed.

In some embodiments, film refers to a layer extending in a direction perpendicular to a thickness direction to cover an entire target or concerned surface, or simply a layer covering a target or concerned surface. In some embodiments, layer refers to a structure having a certain thickness formed on a surface or a synonym of film or a non-film structure. A layer can be continuous or noncontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers.

In this disclosure, continuously can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments. For example, a reactant can be supplied continuously during two or more steps, during a deposition cycle, and/or during two or more deposition cycles of a method.

The term cyclic deposition process or cyclical deposition process or cyclic deposition cycle can refer to a pulsed introduction of a precursor into a reaction chamber and/or use of a pulsed plasma power to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. As described below, such processes can include a plasma step and be referred to as plasma-enhanced processes.

Silicon oxycarbide (SiOC) can refer to material that includes silicon, oxygen, and carbon. As used herein, unless stated otherwise, SiOC is not intended to limit, restrict, or define the bonding or chemical state, for example, the oxidation state of any of Si, C, O, and/or any other element in the film. In some embodiments, SiOC may comprise one or more elements in addition to Si, C, and O, such as H or N. In some embodiments, the SiOC may comprise Si-C bonds and/or Si-O bonds. In some embodiments, the SiOC may comprise Si-H bonds in addition to Si-C and/or Si-O bonds. In some embodiments, the SiOC may comprise greater than 0% to about 60% carbon on an atomic basis. In some embodiments, the SiOC may comprise from about 0.1% to about 40%, from about 0.5% to about 30%, from about 1% to about 30%, or from about 5% to about 20% carbon on an atomic basis. In some embodiments, the SiOC may comprise greater than 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise greater than 0% to about 50% silicon on an atomic basis. In some embodiments, the SiOC may comprise from about 10% to about 50%, from about 15% to about 40%, or from about 20% to about 35% silicon on an atomic basis. In some embodiments, the SiOC may comprise from about 0.1% to about 40%, from about 0.5% to about 30%, from about 1% to about 30%, or from about 5% to about 20% hydrogen on an atomic basis. In some embodiments, the SiOC may not comprise nitrogen. In some cases, the SiOC layer can include from about 0.1% to about 20%, from about 0.5% to about15%, from about 1% to about 10%, or from about 1.5% to about 5% nitrogen on an atomic basis. In some embodiments, the SiOC includes at least one Si-C bond and/or at least one Si-O bond from a precursor, discussed in more detail below. In some embodiments, the SiOC includes nitrogen from a precursor.

As used herein, the term overlap can mean coinciding with respect to time and within a reaction chamber. For example, with regard to gas pulse periods, such as precursor pulse periods and reactant periods, two or more gas periods can overlap when gases from the respective periods are within the reaction chamber or provided to the reaction chamber for a period of time. Similarly, a plasma power period can overlap with a gas (e.g., reactant gas) period (which can be continuous through one or more cycles, described below).

Further, in this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like in some embodiments. Further, in this disclosure, the terms include, including, constituted by and having can refer independently to typically or broadly comprising, consisting essentially of, or consisting of in some embodiments. In this disclosure, any defined meanings do not necessarily exclude ordinary and customary meanings in some embodiments.

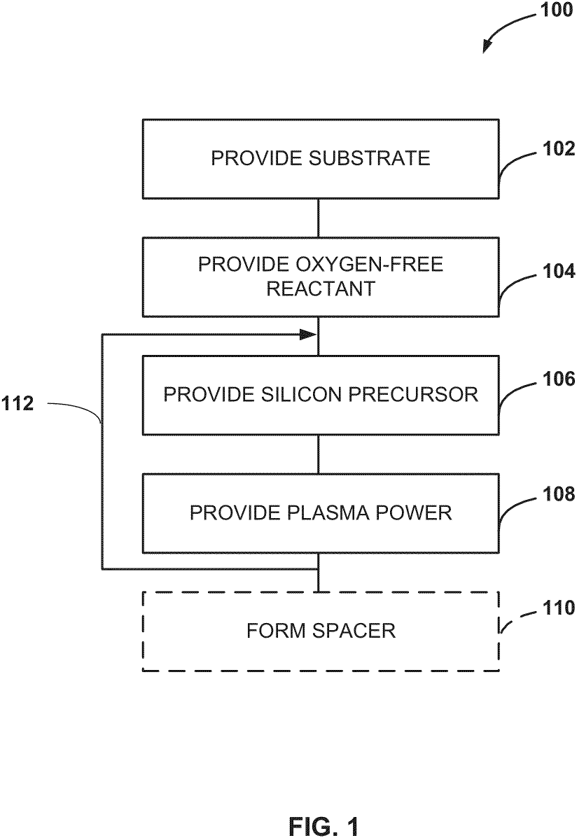

Turning now to the figures, FIG. 1 illustrates a method 100 of forming a silicon oxycarbide layer on a surface of a substrate in accordance with examples of the disclosure. Method 100 can be used to form silicon oxycarbide layers with a relatively high deposition rate, relatively low temperature, relatively low wet etch rates and relatively low dielectric constants. As illustrated, method 100 includes the steps of providing a substrate within a reaction chamber (step 102), providing an oxygen-free reactant to the reaction chamber (step 104), and performing one or more deposition cycles (cycle 112). Each cycle 112 can include providing a silicon precursor to the reaction chamber (step 106), and providing plasma power (step 108). Method 100 can also include an optional step of forming a spacer (step 110).

During step 102, a substrate is provided within a reaction chamber of a reactor. The substrate can be or include any substrate described herein. A reaction chamber used during step 102 can be or include a reaction chamber of a chemical vapor deposition reactor system configured to perform a cyclical deposition process, and particularly, a plasma-enhanced cyclical deposition process. The reaction chamber can be a standalone reaction chamber or part of a cluster tool or module.

Step 102 can include heating the substrate to a desired deposition temperature within the reaction chamber. In some embodiments of the disclosure, step 102 includes heating the substrate to a temperature of less than 600° C. or less than 500° C. For example, in some embodiments of the disclosure, heating the substrate to a deposition temperature may comprise heating the substrate to a temperature that is between about 75° C. and about 550° C. or between about 75° C. and about 500° C. or between about 120° C. and about 300° C. In addition to controlling the temperature of the substrate, a pressure within the reaction chamber may also be regulated. For example, in some embodiments of the disclosure, the pressure within the reaction chamber during step 102 may be greater than 100 Pa and/or be less than 3000 Pa or be between about 300 and about 3000 Pa or between about 400 and about 1500 Pa. These temperatures and pressures are also suitable for steps 104-108.

During step 104, an oxygen-free reactant is provided to the reaction chamber. Exemplary oxygen-free reactants include, for example, one or more of argon (Ar) and hydrogen (H₂). In these cases, the oxygen-free reactant can include about 80 to about 100 or about 90 to about 99.9 volumetric percent argon (Ar) and/or about 0.1 to about 20 or about 0.5 to about 10 volumetric percent hydrogen (H₂). In accordance with specific examples of the disclosure, the oxygen-free reactant is or includes a mixture comprising argon (Ar) and hydrogen (H₂). A flowrate of the oxygen-free reactant to the reaction chamber can be controlled and be between about 100 and about 6000 sccm or between about 1000 and about 4000 sccm.

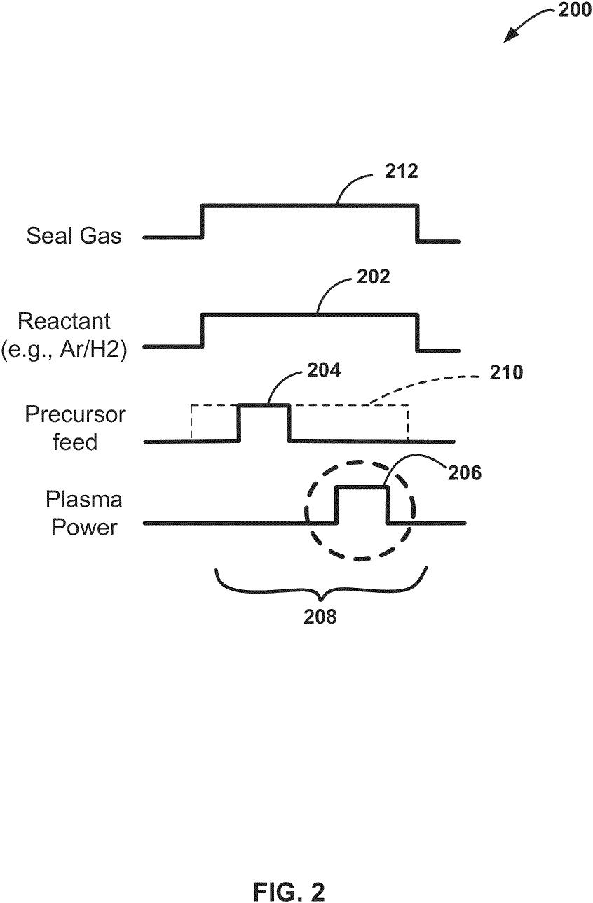

During step 106, a silicon precursor is provided to the reaction chamber for a silicon precursor pulse period. As used herein, pulse period or period means a time in which a gas (e.g., precursor, reactant, inert gas, and/or carrier gas) is flowed to a reaction chamber and/or a period in which power is applied (e.g., power to produce a plasma). In some cases, a period can be continuous through one or more deposition cycles. In some cases, a continuous period can include continuously providing a gas to the reaction chamber. A height and/or width of illustrated pulse periods (illustrated in FIG. 2) is not necessarily indicative of a particular amount or duration of a pulse.

Exemplary silicon precursors suitable for step 106 include a molecule comprising silicon, oxygen, carbon, and optionally nitrogen. The molecule can be represented by the formula: SiₐC_{b}O_{c}H_{d}Nₑ, where a is an integer from at least 1 to at most 2, b is an integer from at least 5 to at most 14, c is an integer from at least 2 to at most 4, d is an integer from at least 12 to at most 30, and e is an integer from at least 0 to at most 2.

Exemplary silicon precursors further include one or more of (i) one or two silicon-oxygen bonds, (ii) one or two silicon-carbon bonds, or (iii) one carbon-carbon double bond. In some cases, the molecule includes two silicon-oxygen bonds and two silicon-carbon bonds. Additionally or alternatively, the molecule comprises the carbon-carbon double bond. In some cases, the molecule can include a silicon-nitrogen bond.

In accordance with further examples, the molecule comprises a backbone structure selected from the group consisting of:

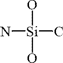

and

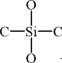

Each C in the backbone can be independently replaced by an independently selected C1-C21 alkyl group. Similarly, each O can be independently replaced with an independently selected C1-C7 alkoxy group. Additionally or alternatively, the N can be replaced with a C1-C14 amine functional group.

Particular exemplary silicon precursors include the following.

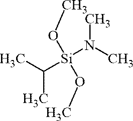

N-[dimethoxy(propan-2-yl)silyl]-N-methylmethanamine

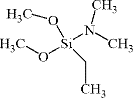

N-[ethyl(dimethoxy)silyl]-N-methylmethanamine

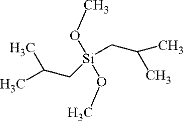

diisobutyldimethoxysilane

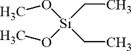

dimethoxydiethylsilane

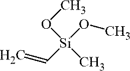

dimethoxymethylvinylsilane.

Other exemplary precursors/molecules include dimethoxymethylvinylsilane, bis(methyldimethoxysilyl)methane, and 1,2-bis(methyldiethoxysilyl)ethane.

A duration of the silicon precursor pulse period can be between about 0.1 and about 2.0 second or between about 0.15 and about 1.0 seconds. A flowrate of the silicon precursor (e.g., with a carrier gas) can be between about 100 and about 6000 sccm or between about 1000 and about 4000 sccm. A mixture of the silicon precursor and the carrier gas can include about 0.1 to about 40 volumetric percent of the silicon precursor.

During step 108, a plasma power is provided to an electrode (e.g., within the reactor) for a plasma power period to form a plasma within the reactor. In some cases, the plasma power may be pulsed during the plasma power period. During this step, the silicon precursor within the reaction chamber can polymerize and form the silicon oxycarbide layer.

A plasma power used during step 108 can be between about 35 and about 1500 W or between about 100 and about 500 W. A duration of the plasma power period can be between 0.01 and 5.0 seconds. A plasma pulse period, i.e., a duration of each pulse of plasma power during the plasma power period, can be between about 0.01 and 0.2 msec. A plasma power on-time duty cycle can be greater than 0 and less than 75% or between about 10 and about 50%. A frequency of the pulsed plasma power can be between about 5000 and 200000 Hz or about 10000 and 100000 Hz.

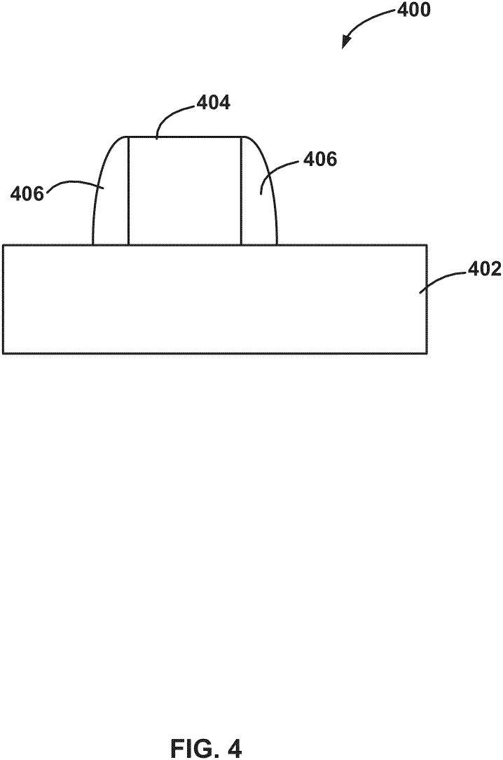

As illustrated, method 100 can include step 110 of forming a spacer. Step 110 can include etching a portion of the silicon oxycarbide layer formed using steps 102-108 to form a spacer about or within a feature on the substrate surface. An exemplary spacer that can form during step 110 is illustrated below in FIG. 4.

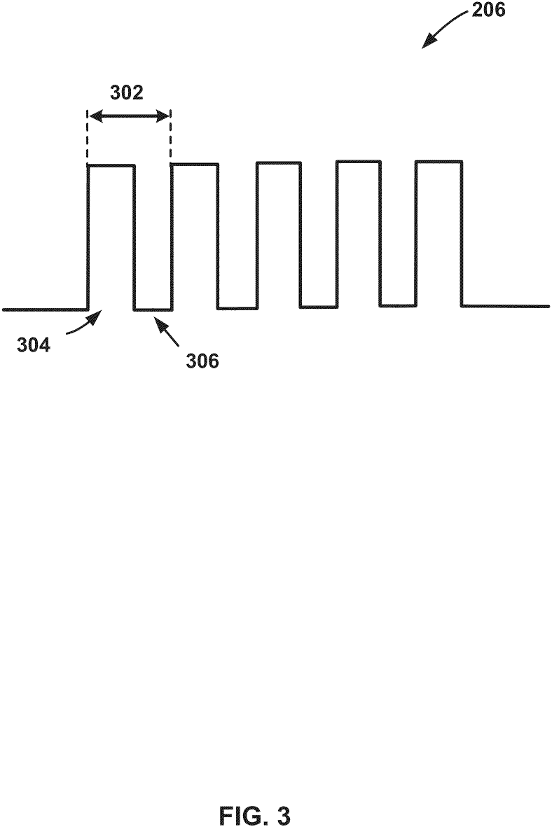

FIGS. 2 and 3 illustrate an exemplary timing sequence 200 suitable for method 100. In the illustrated example, a reactant is provided to the reaction chamber for a reactant period 202, a silicon precursor is provided to the reaction chamber for a silicon precursor pulse period 204, and a plasma power is applied to form a plasma during plasma power period 206. Sequence 200 can include one or more deposition cycles 208. In the illustrated example, each deposition cycle 208 includes a silicon precursor pulse period 204 and a plasma power period 206, while reactant period 202 can be continuous through one or more deposition cycles 208-e.g., the reactant can be continuously provided to the reaction chamber during deposition cycle 208 or during two or more deposition cycles 208.

Sequence 200 can also include a carrier gas period 210. During carrier gas period 210, a carrier gas (e.g., used to facilitate providing a silicon precursor), such as one or more of argon, helium, alone or in any combination, is provided to the reaction chamber. A flowrate of the carrier gas can be between about 100 and about 5000 sccm. Carrier gas period 210 can overlap with reactant period 202.

Sequence 200 can also include a seal gas period 212. During seal gas period 212, an inert gas can be provided to, for example, a transfer region of a reactor, to mitigate flow of process gas to such a region.

In the illustrated example, silicon precursor pulse period 204 ceases prior to plasma power period 206. Reactant period 202 and a carrier gas period 210 can be continuous through one or more deposition cycles 208. In some cases, during a continuous period, a flowrate of the reactant and/or carrier gas can change-e.g., such that a total (e.g., volumetric) flowrate of gas to the reaction chamber remains about constant during an overlap of periods 202, 204, and 210.

FIG. 3 illustrates an exemplary plasma power period 206 in greater detail. In the illustrated example, plasma power period 206 includes a plurality of on-off cycles 302, where each on-off cycle 302 can have an on-time 304 and an off-time 306, where a percent duty or a duty cycle can be on-time/(on-time + off-time). Exemplary durations of plasma power period and duty cycles are provided above.

As noted above, an advantage of methods described herein is that a silicon oxycarbide layer with desired properties can be formed. For example, silicon oxycarbide layers with a dielectric constant of the silicon oxycarbide layer of less than 4.5, less than 4.25, or less than 4 or between about 3.5 and about 4.25 and/or with a wet etch rate of the silicon oxycarbide layer in 0.5% dilute hydrofluoric acid of less than 1 nm/minute, less than 0.8 nm/minute, less than 0.6 nm/minute, or between 0.4 nm/minute and 0.9 nm/minute can be obtained.

FIG. 4 illustrates a structure formed in accordance with examples of the disclosure. Structure 400 includes a substrate 402, a feature 404, and spacer 406. Substrate 402 can be or include any substrate described herein. Feature 404 can include a metallic, semiconductive, or dielectric patterned feature. Spacer 406 can be formed by depositing a silicon oxycarbide layer-e.g., according to method 100 and then removing a portion of the layer.

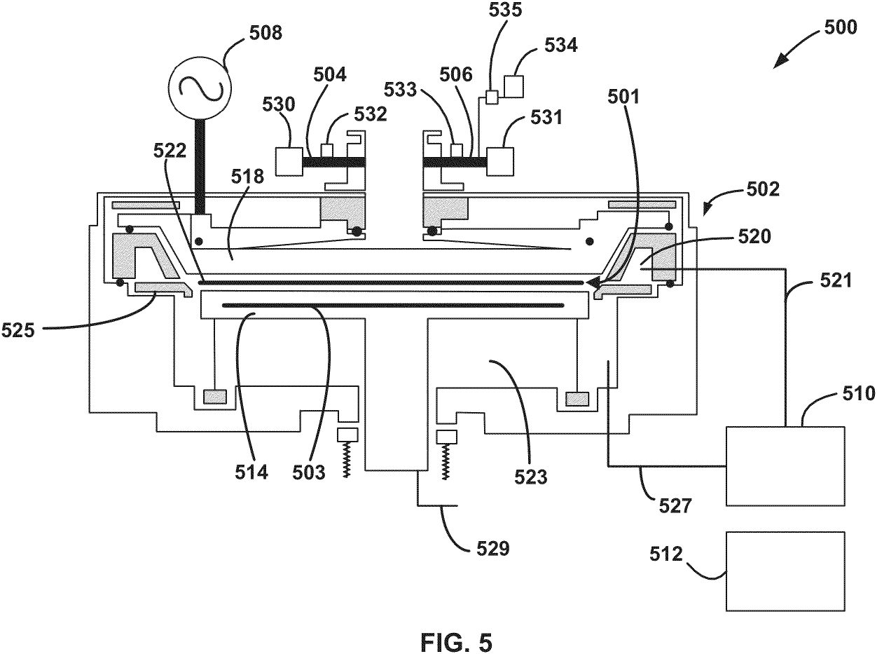

Turning now to FIG. 5, a reactor system 500 in accordance with exemplary embodiments of the disclosure is illustrated. Reactor system 500 can be used to perform one or more steps or substeps as described herein and/or to form one or more structures or portions thereof as described herein.

Reactor system 500 includes a pair of electrically conductive flat-plate electrodes 514, 518 in parallel and facing each other in an interior 501 (reaction zone or reaction chamber) of a reactor 502. Although illustrated with one reactor 502, system 500 can include two or more reactors or reaction chambers. A plasma can be excited within reactor 502 by applying, for example, RF power from plasma power source(s) 508 to one electrode (e.g., electrode 518) and electrically grounding the other electrode (e.g., electrode 514). A temperature regulator 503 can be provided in a lower stage electrode 514 (the lower electrode), and a temperature of a substrate 522 placed thereon can be kept at a desired temperature, such as the temperatures noted above. Electrode 518 can serve as a gas distribution device, such as a shower plate or showerhead. Precursor gases, reactant gases, a carrier or inert gas, and the like can be introduced into reaction space 501 using one or more gas lines (e.g., reactant gas line 504 coupled to a reactant source 530 (e.g., an oxygen-free reactant as described herein)) and precursor gas line 506 coupled to a silicon precursor source 531 and an inert gas source 534. For example, an inert gas and a reactant (e.g., as described above) can be introduced into reaction space 501 using line 504 and/or a precursor and a carrier gas (e.g., as described above) can be introduced into reaction space 501 using line 506. Although illustrated with two inlet gas lines 504, 506, reactor system 500 can include any suitable number of gas lines. A flow control system including flow controllers 532, 533, 535 can be used to control the flow of one or more reactants, precursors, and inert gases into reaction space 501.

In reactor 502, a circular duct 520 with an exhaust line 521 can be provided, through which gas in the interior 501 of reactor 502 can be exhausted to an exhaust source 510. Additionally, a transfer chamber 523 can be provided with a seal gas line 529 to introduce seal gas into the interior of reactor 502 via the interior (transfer zone) of transfer chamber 523, wherein a separation plate 525 for separating the reaction zone 501 and the transfer chamber 523 can be provided (a gate valve through which a substrate is transferred into or from transfer chamber 523 is omitted from this figure). Transfer chamber 523 can also be provided with an exhaust line 527 coupled to an exhaust source 510. In some embodiments, continuous flow of a carrier gas to reaction chamber 501 can be accomplished using a flow-pass system (FPS).

Reactor system 500 can include one or more controller(s) 512 programmed or otherwise configured to cause one or more method steps as described herein to be conducted. Controller(s) 512 are coupled with the various power sources, heating systems, pumps, robotics and gas flow controllers, or valves of the reactor, as will be appreciated by the skilled artisan. By way of example, controller 512 can be configured to control gas flow of a precursor, a reactant, and an inert gas into at least one of the one or more reaction chambers to form a layer on a surface of a substrate. Controller 512 can be further configured to provide power-e.g., within reaction chamber 501. Controller 512 can be similarly configured to perform additional steps as described herein. By way of examples, controller 512 can be configured to control gas flow of a precursor, an inert gas, and a reactant into at least one of the one or more reaction chambers to form a silicon oxycarbide layer overlying a substrate.

Controller 512 can include electronic circuitry and software to selectively operate valves, manifolds, heaters, pumps and other components included in system 500. Such circuitry and components operate to introduce precursors, reactants, and purge gases from the respective sources. Controller 512 can control timing of gas pulse sequences, temperature of the substrate and/or reaction chamber, pressure within the reaction chamber, and various other operations to provide proper operation of the system 500.

Controller 512 can include control software to electrically or pneumatically control valves to control flow of precursors, reactants, and/or purge gases into and out of the reaction chamber 501 and reactor 502. Controller 512 can include modules, such as a software or hardware component, e.g., a FPGA or ASIC, which perform certain tasks. A module can advantageously be configured to reside on the addressable storage medium of the control system and be configured to execute one or more processes.

By way of particular examples, controller 512 is configured to control gas flow of a silicon precursor for a silicon precursor pulse, (e.g., continuous) flow of an oxygen-free reactant during one or more cycles, and a plasma power (e.g., a power level, duration and/or duty cycle of the plasma power).

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 500, substrates, such as semiconductor wafers, are transferred from, e.g., a substrate handling area 523 to the reaction zone 501. Once substrate(s) are transferred to reaction zone 501, one or more gases, such as precursors, reactants, carrier gases, and/or purge gases, are introduced into reaction space 501.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

1. A method of forming a silicon oxycarbide layer on a surface of a substrate, the method comprising the steps of:
providing a substrate within a reaction chamber of a reactor;
providing an oxygen-free reactant to the reaction chamber; and
performing one or more deposition cycles, wherein each deposition cycle comprises:
providing a silicon precursor to the reaction chamber for a silicon precursor pulse period; and
providing plasma power to an electrode for a plasma power period to form a plasma within the reactor,
wherein the silicon precursor comprises a molecule comprising silicon, oxygen, carbon, and optionally nitrogen, the silicon precursor further comprising one or more of (i) one or two silicon-oxygen bonds, (ii) one or two silicon-carbon bonds, or (iii) one carbon-carbon double bond.

2. The method of claim 1, wherein the oxygen-free reactant comprises one or more of argon (Ar) and hydrogen (H₂).

3. The method of claim 1, wherein the oxygen-free reactant comprises about 80 to about 100 or about 90 to about 99.9 volumetric percent argon (Ar).

4. The method of claim 1, wherein the oxygen-free reactant comprises about 0 to about 20 or about 0.1 to about 10 volumetric percent hydrogen (H₂).

5. The method of claim 1, wherein the oxygen-free reactant comprises a mixture comprising argon (Ar) and hydrogen (H₂).

6. The method of claim 1, wherein a duration of the plasma power period is between 0.01 and 5.0 seconds.

7. The method of claim 1, wherein a plasma power on-time duty cycle is greater than 0 and less than 75% or between about 10 and about 50%.

8. The method of claim 1, wherein the molecule comprises a silicon-nitrogen bond.

9. The method of claim 1, wherein the molecule comprises a backbone structure selected from the group consisting of: 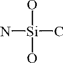
and 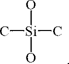
.

10. The method of claim 1, wherein the molecule is represented by the formula:
SiₐC_{b}O_{c}H_{d}Nₑ, where a is an integer from at least 1 to at most 2, b is an integer from at least 5 to at most 14, c is an integer from at least 2 to at most 4, d is an integer from at least 12 to at most 30, and e is an integer from at least 0 to at most 2.

11. The method of claim 1, wherein the molecule comprises two silicon-oxygen bonds and two silicon-carbon bonds.

12. The method of claim 1, wherein the molecule comprises the carbon-carbon double bond.

13. The method of claim 1, wherein the silicon precursor comprises one or more of N-[dimethoxy(propan-2-yl)silyl]-N-methylmethanamine, N-[ethyl(dimethoxy)silyl]-N-methylmethanamine, diisobutyldimethoxysilane, dimethoxydiethylsilane, dimethoxymethylvinylsilane, bis(methyldimethoxysilyl)methane, and 1,2-bis(methyldiethoxysilyl)ethane.

14. The method of claim 1, wherein the silicon oxycarbide layer forms a spacer.

15. The method of claim 1, wherein a dielectric constant of the silicon oxycarbide layer is less than 4.5.

16. The method of claim 1, wherein a wet etch rate of the silicon oxycarbide layer in 0.5% dilute hydrofluoric acid is less than 1 nm/minute.

17. The method of claim 1, wherein the reactant is continuously provided to the reaction chamber during a deposition cycle of the one or more deposition cycles.

18. The method of claim 1, wherein the reactant is continuously provided to the reaction chamber during two or more deposition cycles.

19. The method of claim 1, wherein the silicon precursor pulse period ceases prior to the plasma power period.

20. The method of claim 1, wherein a duration of the silicon precursor pulse period is between about 0.1 and about 2 second or between about 0.15 and about 1 seconds.

21. The method of claim 1, wherein a temperature of the substrate is between about 75 and about 500° C. or between about 120 and about 300° C.

22. The method of claim 1, wherein a pressure within the reaction chamber during the deposition cycle is between about 300 and about 3000 Pa or between about 400 and about 1500 Pa.

23. A structure formed according to the method of claim 1.

24. A reactor system for performing the method of claim 1.
